(19) United States
(12) Patent Application Publication
(10) Pub. No.: US 2014/0117348 A1
(43) Pub. Date: May 1, 2014

(54) Active-matrix Panel Display Device, TFT and Method for Forming the Same

(71) Applicant: Shenzhen China Star Optoelectronics Technology Co. Ltd., Shenzhen, Guangdong (CN)

(72) Inventors: Cheng-Lung Chiang, Shenzhen City (CN); Po-Lin Chen, Shenzhen City (CN)

(73) Assignee: Shenzhen China Star Optoelectronics Technology Co. Ltd., Shenzhen, Guangdong (CN)

(21) Appl. No.: 13/700,658

(22) PCT Filed: Oct. 30, 2012
(86) PCT No.: PCT/CN12/83735

§ 371 Date: Nov. 28, 2012

(30) Foreign Application Priority Data
Oct. 25, 2012 (CN) 201210413187.9

(51) Int. Cl. H01L 29/786; H01L 27/12; H01L 29/26; H01L 29/66

(52) U.S. Cl. CPC H01L 29/78669; H01L 29/66765; H01L 27/1225; H01L 29/263
USPC 257/43; 438/158

(57) ABSTRACT

The present invention discloses an active-matrix panel display device, a TFT and a method for forming the same The method includes that arranging a first insulating layer on a gate, stacking an oxide semiconductor layer and a buffer layer in order on the first insulating layer, arranging as source on the oxide semiconductor layer and a drain on the buffer layer, and plasma processing or heating in oxygen atmosphere the buffer layer which does not directly contact the source and the drain. Therefore, the present invention is capable of preventing the oxide semiconductor layer from damage in follow-up processes to assure stability of the TFT and display quality of the active-matrix panel display device.

### BACKGROUND OF THE INVENTION

1. Field of the Invention

The present invention relates to a display technology field, more particularly, to an active-matrix panel display device, a than film transistor (TFT) and a method for forming the same.

2. Description of the Prior Art

An application of Oxide thin film transistor (TFT) has been achieved. The Oxide TFT technology is that it substitutes silicon semiconductor applied for a-Si TFT for Oxide semiconductor, such as Indium Gallium Zinc Oxide (IGZO), to form a semiconductor layer of the TFT. There are two sorts of structures for Oxide TFT, Back Channel Etched (BCE) and Etch Stopper (ES). In contrast to the ES Oxide TFT, the BCE Oxide TFT has the advantages like simple technology processes and higher channel ratio of width to length.

The oxide semiconductor of the BCE Oxide TFT however, is easily damaged by follow-up processes, e.g. etching a source and a drain or depositing a protection layer, to cause deterioration in properties and instability for Oxide TFT.

### SUMMARY OF THE INVENTION

It is therefore a primary object of the present invention to provide an active-matrix and display device, a thin film transistor (TFT) and a method for forming the same to prevent an oxide semiconductor from damage in follow-up processes to assure stability of the TFT and display quality of the active-matrix panel display device.

According to the present invention, a method of forming a thin film transistor (TFT) comprises the following steps: forming a gate on a substrate; forming a first insulating, layer on the gate; stacking an oxide semiconductor layer and a buffer layer in order on the first insulating layer, wherein the buffer layer is formed by transparent conducting oxides; forming a source and a drain on the oxide semiconductor layer and the buffer layer; plasma processing or heating in oxygen atmosphere the buffer layer which does not directly contact the source and the drain so that oxygen content of the buffer layer which does not directly contact the source and the drain is more than that of the buffer layer which directly contacts the source and the drain.

In one aspect of the present invention, the oxide semiconductor layer is made of at least one of the following oxides, ZnOx, SnOx, InOx and GaOx.

In another aspect of the present invention, the buffer layer is made of at least one of the following oxides, ITO, IZO, AZO and GZO.

In still another aspect of the present invention, the oxide semiconductor layer is thicker than the buffer layer.

In yet another aspect of the present invention, contact between the oxide semiconductor layer and the buffer layer is ohmic contact.

According to the present invention, a thin film transistor comprises a gate, a first insulating layer on the gate, an oxide semiconductor layer and a buffer layer stacked in order on the first insulating layer, a source and a dram on the oxide semiconductor layer and the buffer layer. The buffer layer is made of transparent conducting oxides. Oxygen content of the buffer layer which does not directly contact the source and the drain is more than that of the buffer layer which directly contacts the source and the drain.

In one aspect of the present invention, the oxide semiconductor layer is made of at least one of the following oxides, ZnOx, SnOx, InOx and GaOx.

In another aspect of the present invention, the buffer layer is made of at least one of the following oxides, ITO, IZO, AZO and GZO.

In still another aspect of the present invention, the oxide semiconductor layer is thicker than the buffer layer.

In yet another aspect of the present invention, contact between the oxide semiconductor layer and the buffer layer is ohmic contact.

According to the present invention, an active-matrix panel display device comprising an array substrate is provided. The array substrate comprises a substrate, a gate on the substrate, a first insulating layer on the gate, an oxide semiconductor layer and a buffer layer stacked in order on the first insulating layer, a source and a drain on the oxide semiconductor layer and the buffer layer, a second insulating layer on the source and the drain, a via on the second insulating layer set up at a position corresponding to the drain, a transparent conducting layer on the second insulating, layer connecting with the drain through the via. The buffer layer is made of transparent conducting oxides. Material of the buffer layer is the same with that of the transparent conducting, layer, and oxygen content of the buffer layer which does not directly contact the source and the drain is more than that of the buffer layer which directly contacts the source and the drain.

In one aspect of the present invention, the oxide semiconductor layer is thicker than the buffer layer.

In another aspect of the present invention, the buffer layer is made of at least one of the following oxides, ITO, IZO, AZO and GZO.

In still another aspect of the present invention, the oxide semiconductor layer is made of at least one of the following oxides, ZnOx, SnOx, InOx and GaOx.

In yet another aspect of the present invention, contact between the oxide semiconductor layer and the buffer layer is ohmic contact.

In contrast to prior art, the beneficial effect of the present invention is that the present invention stacks an oxide semiconductor layer and a buffer layer in order on a first insulating layer and respectively forms a source and a drain on the oxide semiconductor layer and the buffer layer. The buffer layer which does not directly contact the source and the drain is applied to plasma process or heating process in oxygen atmosphere so that oxygen content of the buffer layer which does not directly contact the source and the drain is more than that of the buffer layer which directly contacts the source and the drain. Therefore, the buffer layer is capable of protecting the oxide semiconductor layer to prevent the oxide semiconductor layer from damage by follow-up processes so that it assures stability of the TFT and display quality of the active-matrix panel display device.

### BRIEF DESCRIPTION OF THE DRAWINGS

For better understanding embodiments of the present invention, the following detailed description taken in conjunction with the accompanying drawings is provided. Apparently, the accompanying drawings are merely for some of the embodiments of the present invention. Any ordinarily skilled person in the technical field of the present invention could still obtain other accompanying drawings without use laborious invention based on the present accompanying drawings.

FIG. 1 is a flowchart of a method for forming a TFT according to a first embodiment of the present invention.

FIG. 2 is a process diagram corresponding to the method for forming the TFT in FIG. 1.

FIG. 3 illustrates a structure diagram of a TFT according to a second embodiment of the present invention.

FIG. 4 is a structure diagram of an active-matrix panel display device according to a third embodiment of the present invention.

FIG. 5 is a structure diagram of the array substrate in the active-matrix panel display device in FIG. 4.

### DETAILED DESCRIPTION OF THE PREFERRED EMBODIMENTS

The following is a detailed description of the preferred embodiment of the invention.

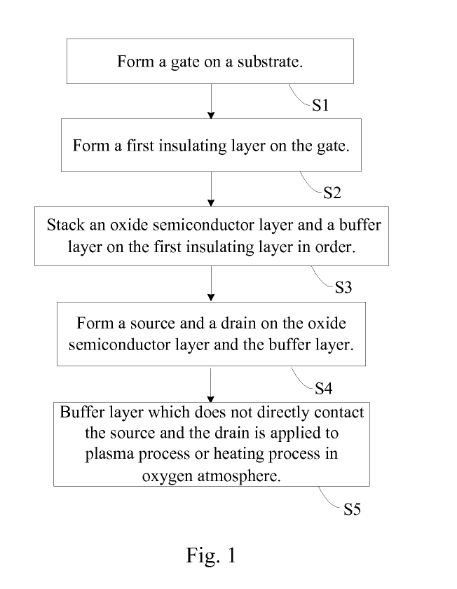

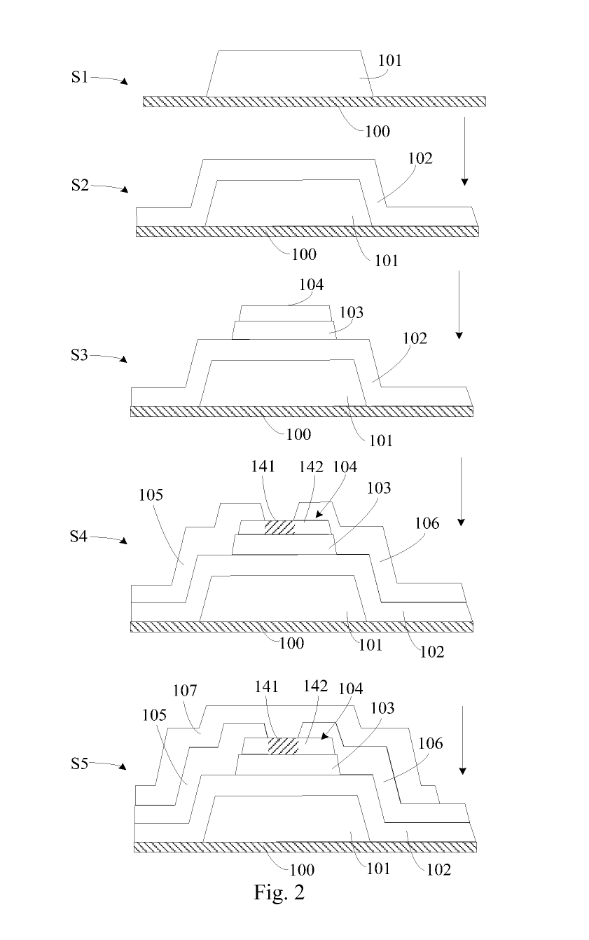

Please refer to FIG. 1 in conjunction with FIG. 2. FIG. 1 is a flowchart of a method for forming a TFT according to a first embodiment of the present invention, and FIG. 2 is a process diagram corresponding to the method for forming the TFT in FIG. 1. The method of forming the TFT composes the following steps:

Step S1: Form a gate 101 on a substrate 100;

the substrate 100 is provided and the gate 101 is arranged on the substrate 100. The gate 101 as a control electrode of a TFT is used for controlling on/off states of the TFT in response to an external signal.

Step S2: Form a first insulating layer 102 on the gate 101;

the first insulating layer 102 formed on the gate is used for insulating the gate 101 from other layers.

Step S3: Stack an oxide semiconductor layer 103 and a buffer layer 104 on the first insulating layer 102 in order;

the oxide semiconductor layer 103 is formed on the first insulating layer 102 and the buffer layer 104 is formed on the oxide semiconductor layer 103.

For simplying the processes, the stack of the butler layer 104 and the oxide semiconductor layer 103 is formed by sputtering thin films and simultaneously etching the thin films with oxalic acid.

In the embodiment, a thickness of the oxide semiconductor layer 103 is larger than that of the buffer layer 104. Preferably, the oxide semiconductor layer 103 is Indium Gallium Zinc Oxides (IGZO) layer made of a group comprising ZnOx, SnOx, InOx, or GaOx. The buffer layer 104 is a transparent conducting layer, preferably formed by transparent conducting oxides, e.g. Indium Tin Oxides (ITO), Indium Zinc Oxides (IZO) Aluminum Zinc Oxides (AZO) and Gallium Zinc Oxides (GZO). The buffer layer 104 is preferred to be ITO and used for prevent the oxide semiconductor 103 from damage in follow-up processes.

Step S4: Form a source 105 and a drain 106 on the oxide semiconductor layer 103 and the buffer layer 104.

In Step S4, the oxide semiconductor layer 103 and the buffer layer 104 stack in order between the source 105, the drain 106 and the first insulating layer 102, the part of the buffer layer 104 which does not directly contact the source 105 and the drain 106 indicates a buffer layer 141, and the part of the buffer layer 104 which directly contacts the source 105 and the drain 106 indicates a buffer layer 142.

The oxide semiconductor layer 103 and the buffer layer 104 is ohmic contact so that it decreases a resistance value in a junction between the source 105, the drain 106 and the buffer layer 104 to the semiconductor layer 103.

Step S5: The buffer layer 141 which does not directly contact the source 105 and the drain 106 is applied to plasma process or heating process in oxygen atmosphere.

In Step SS, the buffer layer 141 is applied to plasma process or heating process in oxygen atmosphere subsequent to the arrangement of the source 105 and the drain 106 so that oxygen content of the buffer layer 141 is more than that of the buffer layer 142. The butler layer 141 becomes a high impendence protective film due to higher oxygen content of the buffer layer 141, thereby preventing the oxide semiconductor layer 103 from the influence of plasma and moisture that causes damage to the oxide semiconductor layer 103 in following processes, to assure stability of the TFT.

A second insulating layer 107 is formed on the source 105 and the drain 106 after processing the buffer layer 104. The second insulating layer 107 contacts the buffer layer 141 and is used for protecting the source 105, the drain 106, the butler layer 104 and the oxide semiconductor layer 103 from damage.

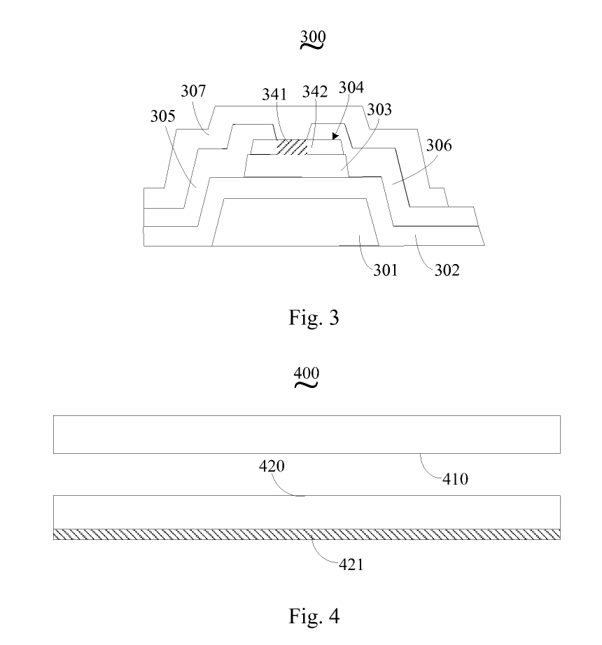

Please refer to FIG. 3. FIG. 3 illustrates a structure diagram of a TFT according to a second embodiment of the present invention. As FIG. 3 shows, a TFT 300 comprises to gate 301, a first insulating layer 302, an oxide semiconductor layer 303, a buffer layer 304, a source 305, a drain 306, and a second insulating layer 307.

The first insulating layer 302 on the gate 301 is a gate insulating layer. The oxide semiconductor layer 303 and the buffer layer 304 stack in order on the first insulating layer 301. The oxide semiconductor layer 303 is close to the first insulating layer 302, and the buffer layer 304 is on the oxide semiconductor layer 303. The buffer layer 304 comprises a butler layer 341 which does not contact the source 305 and the drain 306 directly and a buffer layer 342 which contacts the source 305 and the drain 306 directly. The stack of the buffer layer 304 and the oxide semiconductor layer 303 is formed by sputtering thin films and etching the thin films by oxalic acid at the same time, thereby simplifying the processes.

The source 305 on the oxide semiconductor layer 303 and the drain 306 on the buffer layer 304 is simultaneously formed by the same metal layer. Oxygen content of the buffer layer 341 which does not directly contact the source 305 and the drain 306 is more than that of the buffer layer 342 which directly contacts the source 305 and the drain 306.

Specifically, the buffer layer 341 is applied to plasma process or heating process in oxygen atmosphere to increase an oxygen content of the buffer layer 341. The butler layer 341 becomes a high impendence protective film prevents the oxide semiconductor layer 303 from the influence of plasma and moisture that causes damage to the oxide semiconductor layer 303 in following processes, to assure stability of the TFT.

The oxide semiconductor layer 303 and the buffer layer 304 is ohmic contact so that it decreases a resistance value in a junction between the source 305, the drain 306 and the buffer layer 304 to the semiconductor layer 303.

In this embodiment, a thickness of the oxide semiconductor layer 303 is larger than that of the buffer layer 304. Preferably, the oxide semiconductor layer 303 is Indium Gallium Zinc Oxides (IGZO) layer made of a group comprising ZnOx, SnOx, InOx or GaOx. The buffer layer 304 is a transparent conducting oxides, e.g. Indium Tin Oxides (ITO), Indium Zinc Oxides (IZO), Aluminum Zinc Oxides (AZO) and Gallium Zinc Oxides (GZO).

Referring to FIG. 4, FIG. 4 is a structure diagram of an active-matrix panel display device according to a third embodiment of the present invention. As FIG. 4 shows, an active-matrix panel display device 400 comprises a color filter substrate 410 and an array substrate 420 set up relatively.

The array substrate 420 comprises a substrate 421. Preferably, material of the substrate 421 is glass. By coating and etching processes, the main elements, such as scan lines, data lines, pixel electrodes and TFTs, are formed on the substrate 421.

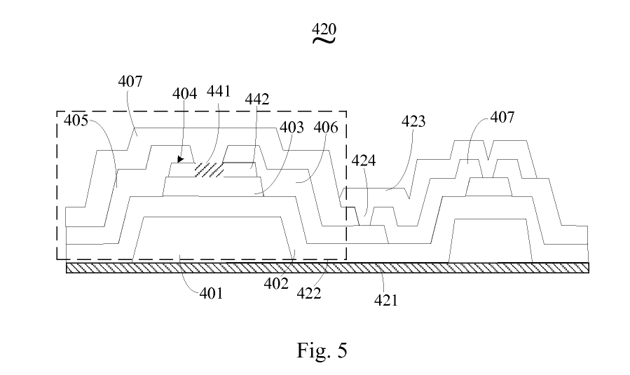

Please refer to FIG. 5, FIG. 5 is a structure diagram of the array substrate 420 in the active-matrix panel display device in FIG. 4. As FIG. 5 shows, the array substrate 420 comprises the substrate 421, a TFT 422 and a transparent conducting layer 423. The structure of the TFT 422 is the same with that of the TFT 300 in FIG. 3.

In the embodiment, the transparent conducting layer 423 as a pixel electrode of the array substrate 420 is on the second insulating layer 407 in which arranges a via 424 at the position correspondent to the drain 406 so that the transparent conducting layer 423 electrically connects with the drain 406 of the TFT 422 through the via 424.

The oxide semiconductor layer 403 and the buffer layer 404 stack in order on the first insulating layer 402, and the thickness of the oxide semiconductor layer 403 is larger than that of the buffer layer 404. The stack of the oxide semiconductor layer 403 and the buffer layer 404 is formed by sputtering thin films and etching the thin films by oxalic acid at the same time, thereby simplifying the processes.

The source 405 and the drain 406 are respectively set up on the oxide semiconductor layer 403 and the buffer layer 404. The oxide semiconductor layer 403 and the buffer layer 404 is ohmic contact so that it decreases a resistance value in a junction between the source 405, the drain 306 and the buffer layer 404 to the semiconductor layer 403.

The buffer layer 404 comprises a buffer layer 441 which does not directly contact the source 405 and the drain 406 and a buffer layer 442 which directly contacts the source 405 and the drain 406, and oxygen content of the buffer layer 441 is more than that of the buffer layer 442. Therefore, a high impendence protective film of the buffer layer 441 is formed to protects the oxide semiconductor layer 403 from the influence of plasma and moisture in processes so that it avoids the damage to the oxide semiconductor layer 403 in follow-up processes to assure stability of the TFT.

In the embodiment, material of the buffer layer 404 is the same with that of the transparent conducting layer 423. The buffer layer 404 is formed by transparent conducting oxides. More particularly, the buffer layer 404 is made of at least one of the following oxides, ITO, IZO, AZO and GZO and preferred to be ITO layer. The oxide semiconductor layer 403 is preferred to be IGZO layer and is made of at least one of the following oxides transparent oxides, ZnOx, Ox, InOx and GaOx.

In sum, the present invention proposes that an oxide semiconductor layer and a buffer layer are stacked in order on as first insulating layer, and a source and a drain are formed on the oxide semiconductor layer and the butler layer. The buffer layer Which does not directly contact the source and the drain is applied to plasma process or heating in oxygen atmosphere so that oxygen content of the buffer layer which does not directly contact the source and the drain is more than that of the buffer layer Which directly contacts the source and the drain. Therefore, the buffer layer is capable of protecting the oxide semiconductor layer to prevent the oxide semiconductor layer from damage by follow-up processes so that it assures stability of the TFT and display quality of the active-matrix panel display device. Furthermore, the oxide semiconductor layer and the buffer layer is ohmic contact so that it decreases a resistance value in a junction between the source, the drain and the butler layer to the semiconductor layer. In addition, the buffer layer on the oxide semiconductor layer is transparent conducting oxides, and the stack of the buffer layer and the oxide semiconductor layer is formed by sputtering thin film and etching the thin films by oxalic acid at the same time, thereby simplifying the processes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a thin film transistor (TFT) comprising:
forming a gate on a substrate;
forming a first insulating layer on the gate;
stacking an oxide semiconductor layer and a buffer layer in order on the first insulating layer, wherein the buffer layer is formed by transparent conducting oxides;
forming a source and a drain on the oxide semiconductor layer and the buffer layer;
plasma processing or heating in oxygen atmosphere the buffer layer which does not directly contact the source and the drain so that oxygen content of the buffer layer which does not directly contact the source and the drain is more than that of the buffer layer which directly contacts the source and the drain.

2. The method of claim 1, wherein the oxide semiconductor layer is made of at least one of the following oxides, ZnOx, SnOx, InOx and GaOx.

3. The method of claim 1, wherein the buffer layer is made of at least one of the following oxides, ITO, IZO, AZO and GZO.

4. The method of claim 1, wherein the oxide semiconductor layer is thicker than the buffer layer.

5. The method of claim 1, wherein contact between the oxide semiconductor layer and the buffer layer is ohmic contact.

6. A thin film transistor, comprising:
a gate;
a first insulating layer on the gate;
an oxide semiconductor layer and a buffer layer stacked in order on the first insulating layer, the buffer layer being made of transparent conducting oxides;
a source and a drain on the oxide semiconductor layer and the buffer layer;
wherein oxygen content of the buffer layer which does not directly contact the source and the drain is more than that of the buffer layer which directly contacts the source and the drain.

7. The thin film transistor of claim 6, wherein the oxide semiconductor layer is made of at least one of the following oxides, ZnOx, SnOx, InOx and GaOx.

8. The thin film transistor of claim 6, wherein the buffer layer is made of at least one of the following oxides, ITO, IZO, AZO and GZO.

9. The thin film transistor of claim 6, wherein the oxide semiconductor layer is thicker than the buffer layer.

10. The thin film transistor claim 6, wherein contact between the oxide semiconductor layer and the buffer layer is ohmic contact.

11. An active-matrix panel display device comprising an array substrate, the array substrate comprising:
a substrate;
a gate on the substrate;
a first insulating layer on the gate;
an oxide semiconductor layer and a buffer layer stacked in order on the first insulating layer, the buffer layer being made of transparent conducting oxides;
a source and a drain on the oxide semiconductor layer and the buffer layer;
a second insulating layer on the source and the drain, a via on the second insulating layer set up at a position corresponding to the drain;
a transparent conducting layer on the second insulating layer connecting with the drain through the via;
wherein material of the buffer layer is the same with that of the transparent conducting layer, and oxygen content of the buffer layer which does not directly contact the source and the drain is more than that of the buffer layer which directly contacts the source and the drain.

12. The active-matrix panel display device of claim 11, wherein the oxide semiconductor layer is thicker than the buffer layer.

13. The active-matrix panel display device of claim 11, wherein the buffer layer is made of at least one of the following oxides, ITO, IZO, AZO and GZO.

14. The active-matrix panel display device of claim 11, wherein the oxide semiconductor layer is made of at least one of the following oxides, ZnOx, SnOx, InOx and GaOx.

15. The active-matrix panel display device of claim 11, wherein contact between the oxide semiconductor layer and the buffer layer is ohmic contact.
